(19) United States
(12) Patent Application Publication
(10) Pub. No.: US 2025/0313936 A1
(43) Pub. Date: Oct. 9, 2025

(54) DEPOSITION MASK

(71) Applicant: Samsung Display Co., LTD., Yongin-si (KR)

(72) Inventors: Jeong Kuk KIM, Yongin-si (KR); Duck Jung LEE, Yongin-si (KR); Ji Hyun JUNG, Yongin-si (KR); Sung Won CHO, Yongin-si (KR); Jun Ho JO, Yongin-si (KR)

(21) Appl. No.: 18/979,931

(22) Filed: Dec. 13, 2024

(30) Foreign Application Priority Data
Apr. 8, 2024 (KR) 10-2024-0047243

(51) Int. Cl. C23C 14/04; C23C 14/24; H10K 59/12

(52) U.S. Cl. CPC C23C 14/042; C23C 14/24; H10K 59/12

(57) ABSTRACT

A deposition mask includes a cell area, a cell peripheral area surrounding the cell area, and a grid area positioned between the cell area and the cell peripheral area in a plan view, the deposition mask. The deposition mask includes a mask membrane disposed in the cell area, including a mask shadow and defining a pixel opening therein; a mask frame disposed in the cell peripheral area and the gird area; and a plurality of ruler patterns disposed in the grid area, where the plurality of ruler patterns are adjacent to each other in a direction parallel to a major surface of the mask frame and spaced apart at equal intervals.

This application claims priority to Korean Patent Application No. 10-2024-0047243, filed on Apr. 8, 2024, and all the benefits accruing therefrom under 35 U.S.C. § 119, the content of which in its entirety is herein incorporated by reference.

### BACKGROUND

### 1. Technical Field

The present disclosure relates to a deposition mask.

### 2. Description of the Related Art

A wearable device that is developed in the form of glasses or a helmet and focuses on a distance close to the user's eyes is being developed. For example, the wearable device may be a head mounted display (“HMD”) device or AR glass. Such a wearable device provides a user with an augmented reality (hereinafter, referred to as “AR”) screen or a virtual reality (hereinafter, referred to as “VR”) screen.

The wearable device such as the HMD device or the AR glass requires a display specification of at least 2000 pixels per inch (“PPI”) to allow the user to use the device for a long time without feeling dizzy. To this end, organic light emitting diode on silicon (“OLEDoS”) technology, which is a small organic light emitting display device with high resolution, is emerging. The OLEDOS is a technology that disposes organic light emitting diodes (“OLEDs”) on a semiconductor wafer substrate on which a complementary metal oxide semiconductor (“CMOS”) is disposed.

### SUMMARY

The aspects of the present disclosure provide a deposition mask capable of manufacturing a high-resolution display panel.

The aspects of the present disclosure also provide a deposition mask capable of measuring a positional precision of a pixel opening.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

Details of other embodiments are included in the detailed description and drawings.

In an embodiment of the disclosure, a deposition mask includes a cell area, a cell peripheral area surrounding the cell area, and a grid area positioned between the cell area and the cell peripheral area in a plan view. The deposition mask includes a mask membrane disposed in the cell area, including a mask shadow and defining a pixel opening; a mask frame disposed in the cell peripheral area and the grid area; and a plurality of ruler patterns disposed in the grid area, where the plurality of ruler patterns are adjacent to each other in a direction parallel to a major surface of the mask frame and spaced apart at equal intervals.

In an embodiment, the mask frame may include a mask substrate disposed in the cell peripheral area and an upper inorganic layer positioned on the mask substrate, and the upper inorganic layer may include a protrusion that protrudes further toward the cell area than a side surface of the mask substrate positioned toward the cell area.

In an embodiment, the protrusion of the upper inorganic layer may be disposed in the grid area.

In an embodiment, the plurality of ruler patterns may be positioned on the upper inorganic layer, and the plurality of ruler patterns may overlap the protrusion of the upper inorganic layer in a direction perpendicular to the major surface of the mask frame.

In an embodiment, the plurality of ruler patterns may include an inorganic insulating material.

In an embodiment, a height of each of the ruler patterns in the direction perpendicular to the major surface of the mask frame may be equal to or more than 0.2 micrometer and equal to or less than 3.0 micrometer.

In an embodiment, the plurality of ruler patterns may include metal.

In an embodiment, a height of each of the ruler patterns in the direction perpendicular to the major surface of the mask frame may be equal to or more than 50 nanometers and equal to or less than 500 nanometers.

In an embodiment, a gap between the plurality of ruler patterns adjacent to each other in the direction parallel to the major surface of the mask frame may be equal to or more than 10 nanometers and equal to or less than 1000 nanometers.

In an embodiment, in a cross-sectional view, each of the ruler patterns may have a cylindrical shape.

In an embodiment, in a cross-sectional view, each of the ruler patterns may have a trapezoidal shape.

In an embodiment, in a cross-sectional view, each of the ruler patterns may have an inverted tapered shape.

In an embodiment, each of the ruler patterns may include a lower surface facing the upper inorganic layer, an upper surface opposite to the lower surface, and a side surface connecting the upper surface and the lower surface, and the side surface of each of the ruler patterns includes a first side surface connected to the upper surface and a second side surface connected to the lower surface.

In an embodiment, an inclination angle formed by the first side surface and the second side surface may be an obtuse angle.

In an embodiment, at least one of the ruler patterns may be located to point a predetermined position of the pixel opening.

In an embodiment of the disclosure, a deposition mask includes a cell area, a cell peripheral area surrounding the cell area, and a grid area positioned between the cell area and the cell peripheral area in a plan view. The deposition mask includes a mask membrane disposed in the cell area, defining a pixel opening therein and including a mask shadow surrounding the pixel opening; a mask frame disposed in the cell peripheral area and the grid area and defining a mask opening therein; and a plurality of ruler patterns disposed in the grid area, where in the plan view, the plurality of ruler patterns are positioned adjacent to each other and spaced at equal intervals.

In an embodiment, in the plan view, a gap between the plurality of ruler patterns adjacent to each other may be equal to or more than 10 nanometers and equal to or less than 1000 nanometers.

In an embodiment, in the plan view, the mask opening may overlap the cell area, and in the plan view, the plurality of ruler patterns may be positioned to surround the mask opening.

In an embodiment, in the plan view, the ruler patterns may surround an entirety of the mask membrane, and in the plan view, the mask frame may surround an entirety of the ruler patterns.

In an embodiment, in the plan view, the mask frame may include a mask substrate including silicon, and in the plan view, the mask substrate may have a circular shape.

According to the deposition mask according to an embodiment, by forming a mask membrane in a portion overlapping a cell region of a mask substrate, a deposition mask for manufacturing a high-resolution display panel may be provided. In addition, the deposition mask according to an embodiment may measure the positional precision of the pixel opening by forming a nano-ruler pattern in the portion that overlaps the grid area of the mask substrate.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a head mounted electronic device according to an embodiment;

FIG. 2 is an exploded perspective view illustrating an example of the head mounted electronic device of FIG. 1;

FIG. 3 is a perspective view illustrating a head mounted electronic device according to an embodiment;

FIG. 4 is an exploded perspective view illustrating a display device according to an embodiment;

FIG. 5 is a cross-sectional view illustrating an example in which a portion of a display panel according to an embodiment is cut;

FIG. 6 is a schematic plan view of a mask according to an embodiment;

FIG. 7 is an enlarged plan view of area A of FIG. 6;

FIG. 8 is a cross-sectional view taken along line X1-X1′ of FIG. 7;

FIG. 9 is an enlarged plan view of area C of FIG. 7;

FIG. 10 is a cross-sectional view taken along line C1-C1′ of FIG. 9; and

FIGS. 11 to 13 are cross-sectional views illustrating various shapes of a ruler pattern of FIG. 10, according to still another embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms.

These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described in detail with reference to the accompanying drawings.

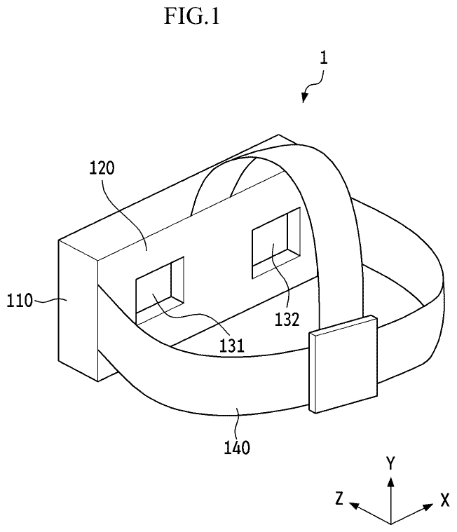

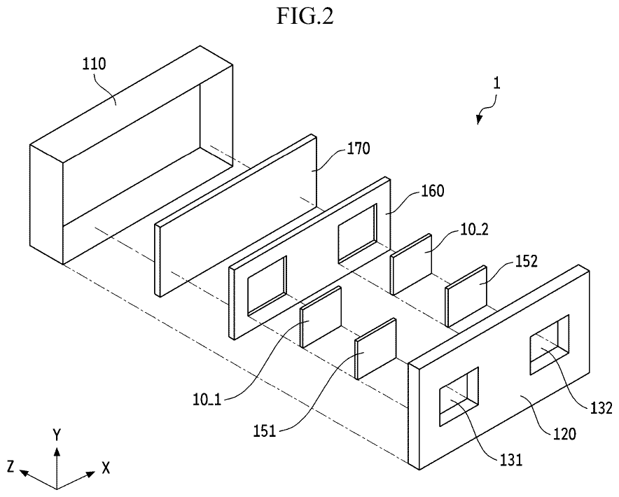

FIG. 1 is a perspective view illustrating a head mounted electronic device according to an embodiment. FIG. 2 is an exploded perspective view illustrating an example of the head mounted electronic device of FIG. 1.

Referring to FIGS. 1 and 2, a head mounted electronic device 1 according to an embodiment includes a display device accommodating portion 110, an accommodating portion cover 120, a first eyepiece 131, a second eyepiece 132, a head mounting band 140, a first display device 10_1, a second display device 10_2, a middle frame 160, a first optical member 151, a second optical member 152, a control circuit board 170, and a connector.

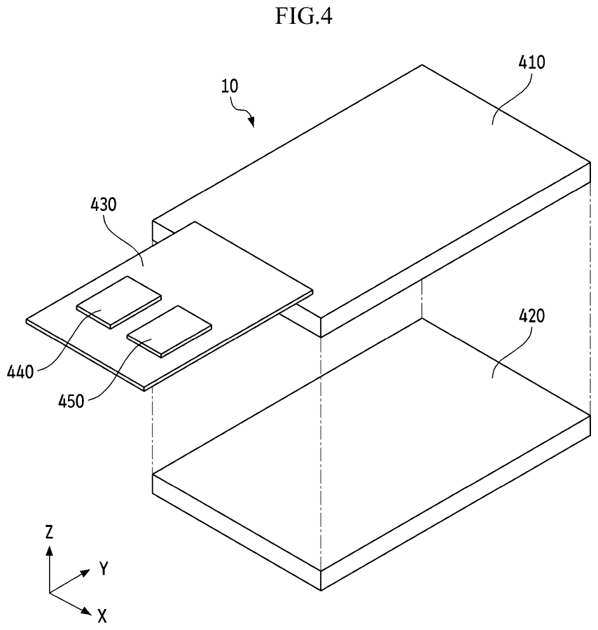

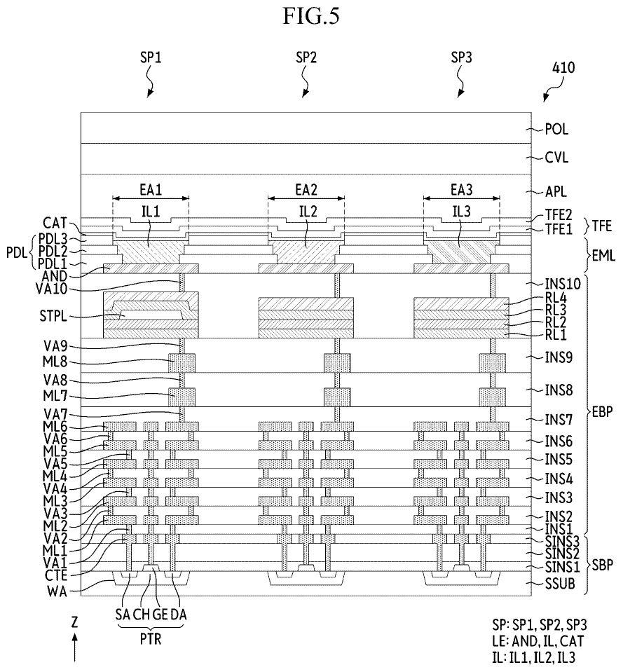

The first display device 10_1 provides an image to a user's left eye, and the second display device 10_2 provides an image to a user's right eye. Each of the first display device 10_1 and the second display device 10_2 is substantially the same as a display device 10 described with reference to FIGS. 4 and 5. Accordingly, descriptions of the first display device 10_1 and the second display device 10_2 will be replaced with descriptions with reference to FIGS. 4 and 5.

The first optical member 151 may be disposed between the first display device 10_1 and the first eyepiece 131. The second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170 and may be disposed between the second display device 10_2 and the control circuit board 170. The middle frame 160 serves to support and fix the first display device 10_1, the second display device 10_2, and the control circuit board 170.

The control circuit board 170 may be disposed between the middle frame 160 and the display device accommodating portion 110. The control circuit board 170 may be connected to the first display device 10_1 and the second display device 10_2 through the connector. The control circuit board 170 may convert an image source input from the outside into digital video data DATA, and may transmit the digital video data DATA to the first display device 10_1 and the second display device 10_2 through the connector.

The control circuit board 170 may transmit digital video data DATA corresponding to a left eye image optimized for the user's left eye to the first display device 10_1, and may transmit digital video data DATA corresponding to a right eye image optimized for the user's right eye to the second display device 10_2. Alternatively, the control circuit board 170 may transmit the same digital video data DATA to the first display device 10_1 and the second display device 10_2.

The display device accommodating portion 110 serves to accommodate the first display device 10_1, the second display device 10_2, the middle frame 160, the first optical member 151, the second optical member 152, the control circuit board 170, and the connector. The accommodating portion cover 120 is disposed to cover one opened surface of the display device accommodating portion 110. The accommodating portion cover 120 may include a first eyepiece 131 where the user's left eye is disposed and a second eyepiece 132 where the user's right eye is disposed. It is illustrated in FIGS. 1 and 2 that the first eyepiece 131 and the second eyepiece 132 are separately disposed, but the embodiment of the present specification is not limited thereto. The first eyepiece 131 and the second eyepiece 132 may be integrated into one in another embodiment.

The first eyepiece 131 may be aligned with the first display device 10_1 and the first optical member 151, and the second eyepiece 132 may be aligned with the second display device 10_2 and the second optical member 152. Therefore, the user may view an image of the first display device 10_1 magnified as a virtual image by the first optical member 151 through the first eyepiece 131, and may view an image of the second display device 10_2 magnified as a virtual image by the second optical member 152 through the second eyepiece 132.

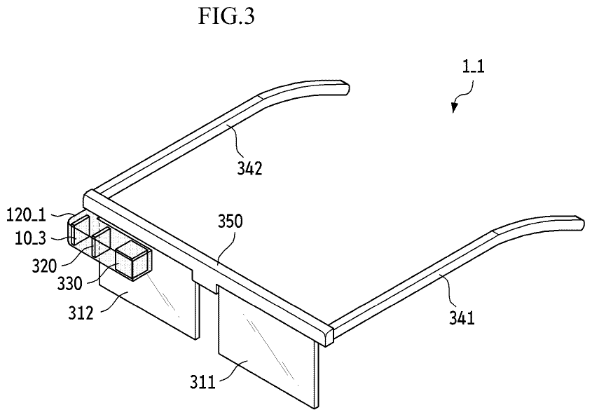

The head mounting band 140 serves to fix the display device accommodating portion 110 to a user's head so that the first eyepiece 131 and the second eyepiece 132 of the accommodating portion cover 120 are disposed on the user's left and right eyes, respectively. When the display device accommodating portion 110 is implemented in a lightweight and small size, the head mounted electronic device 1 may include eyeglass frames as illustrated in FIG. 3 instead of the head mounting band 140.

In addition, the head mounted electronic device 1 may further include a battery for supplying power, an external memory slot for accommodating an external memory, and an external connection port and a wireless communication module for receiving an image source. The external connection port may be a universe serial bus (“USB”) terminal, a display port, or a high-definition multimedia interface (“HDMI”) terminal, and the wireless communication module may be a 5G communication module, a 4G communication module, a Wi-Fi module, or a Bluetooth module.

FIG. 3 is a perspective view illustrating a head mounted electronic device according to an embodiment.

Referring to FIG. 3, a head mounted electronic device 1_1 according to an embodiment may be a glasses-type display device in which a display device accommodating portion 120_1 is implemented in a lightweight and small size. The head mounted electronic device 1_1 according to an embodiment may include a display device 10_3, a left eye lens 311, a right eye lens 312, a support frame 350, eyeglass frame legs 341 and 342, an optical member 320, a light path conversion member 330, and a display device accommodating portion 120_1.

The display device 10_3 illustrated in FIG. 3 is substantially the same as the display device 10 described with reference to FIGS. 4 and 5. Accordingly, descriptions of the first display device 10_1 and the second display device 10_2 will be replaced with descriptions with reference to FIGS. 4 and 5.

The display device accommodating portion 120_1 may include the display device 10_3, the optical member 320, and the light path conversion member 330. As an image displayed on the display device 10_3 is magnified by the optical member 320 and a light path thereof is converted by the light path conversion member 330, the image may be provided to the user's right eye through the right eye lens 312. Accordingly, the user may view an augmented reality image in which a virtual image displayed on the display device 10_3 and a real image viewed through the right eye lens 312 are combined through the right eye.

It is illustrated in FIG. 3 that the display device accommodating portion 120_1 is disposed at a right distal end of the support frame 350, but the embodiment of the present specification is not limited thereto. For another example, the display device accommodating portion 120_1 may be disposed at a left distal end of the support frame 350, and in this case, the image of the display device 10_3 may be provided to the user's left eye. Alternatively, the display device accommodating portions 120_1 may be disposed at both the left and right distal ends of the support frame 350. In this case, the user may view the image displayed on the display device 10_3 through both the user's left and right eyes.

FIG. 4 is an exploded perspective view illustrating a display device according to an embodiment.

Referring to FIG. 4, a display device 10 according to an embodiment is a device that displays a moving image or a still image. The display device 10 according to an embodiment may be applied to portable electronic devices such as a mobile phone, a smart phone, a tablet personal computer (“PC”), a mobile communication terminal, an electronic notebook, an electronic book, a portable multimedia player (“PMP”), navigation, and an ultra-mobile PC (“UMPC”). For example, the display device 10 may be applied to a display unit of a television, a laptop computer, a monitor, a billboard, or the Internet of Things (“IoT”). Alternatively, the display device 10 may be applied to a smart watch, a watch phone, and a head mounted display (HMD) for implementing virtual reality and augmented reality.

The display device 10 according to an embodiment includes a display panel 410, a heat dissipation layer 420, a circuit board 430, a driving circuit 440, and a power supply circuit 450.

The display panel 410 may have a planar shape similar to a quadrangle. For example, the display panel 410 may have a planar shape similar to a quadrangle having short sides in a first direction DR1 (X-axis direction) and long sides in a second direction DR2 (Y-axis direction) intersecting the first direction DR1 (X-axis direction). In the display panel 410, a corner where the short side in the first direction (X-axis direction) and the long side in the second direction (Y-axis direction) meet each other may be formed at a right angle or may have a round shape so as to have a predetermined curvature. The planar shape of the display panel 410 is not limited to the quadrangle, and may be formed similarly to other polygons, circles, or ovals. A planar shape of the display device 10 may follow the planar shape of the display panel 410, but the embodiment of the present specification is not limited thereto.

The display panel 410 includes a display area that displays an image and a non-display area that does not display an image.

The display area includes a plurality of pixels, and each of the plurality of pixels includes a plurality of sub-pixels (SP1, SP2, and SP3 in FIG. 5). The plurality of sub-pixels SP1, SP2, and SP3 include a plurality of pixel transistors. The plurality of pixel transistors may be formed through a semiconductor process and may be disposed on a semiconductor substrate (SSUB in FIG. 5). For example, the plurality of pixel transistors may be formed of a complementary metal oxide semiconductor (CMOS).

The heat dissipation layer 420 may overlap the display panel 410 in a third direction (Z-axis direction), which is a thickness direction of the display panel 410. The heat dissipation layer 420 may be disposed on one surface of the display panel 410, for example, a rear surface thereof. The heat dissipation layer 420 serves to dissipate heat generated from the display panel 410. The heat dissipation layer 420 may include a metal layer such as graphite, silver (Ag), copper (Cu), or aluminum (Al) having high thermal conductivity.

The circuit board 430 may be electrically connected to a plurality of pads PD of a pad area PDA of the display panel 410 by using a conductive adhesive member such as an anisotropic conductive film. The circuit board 430 may be a flexible printed circuit board or flexible film made of a flexible material. It is illustrated in FIG. 4 that the circuit board 430 is unfolded, but the circuit board 430 may be bent. In this case, one end of the circuit board 430 may be disposed on the rear surface of the display panel 410. One end of the circuit board 430 may be an opposite end of the other end of the circuit board 430 connected to the plurality of pads PD of the pad area PDA of the display panel 410 by using a conductive adhesive member.

The driving circuit 440 may receive digital video data and timing signals from the outside. The driving circuit 440 may generate a scan timing control signal, an emission timing control signal, and a data timing control signal for controlling the display panel 410 according to the timing signals.

The power supply circuit 450 may generate a plurality of panel driving voltages according to a power voltage from the outside.

The driving circuit 440 and the power supply circuit 450 may be each formed as an integrated circuit (“IC”) and attached to one surface of the circuit board 430.

FIG. 5 is a cross-sectional view illustrating an example in which a portion of a display panel according to an embodiment is cut. For example, FIG. 5 illustrates a partial cross-sectional structure of a display area including a plurality of sub-pixels (SP1, SP2, and SP3 in FIG. 5).

Referring to FIG. 5, the display panel 410 includes a semiconductor backplane SBP, a light emitting element backplane EBP, a light emitting element layer EML, an encapsulation layer TFE, an optical layer OPL, and a cover layer CVL.

The semiconductor backplane SBP includes a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively.

The semiconductor substrate SSUB may be a silicon substrate, a germanium substrate, or a silicon-germanium substrate. The semiconductor substrate SSUB may be a substrate doped with first-type impurities. A plurality of well areas WA may be disposed on an upper surface of the semiconductor substrate SSUB. The plurality of well areas WA may be areas doped with second-type impurities. The second-type impurity may be different from the first-type impurity described above. For example, when the first-type impurity is a p-type impurity, the second-type impurity may be an n-type impurity. Alternatively, when the first-type impurity is an n-type impurity, the second-type impurity may be a p-type impurity.

The semiconductor substrate SSUB may be replaced with a glass substrate or a polymer resin substrate such as polyimide. In this case, thin film transistors may be disposed on the glass substrate or the polymer resin substrate. The glass substrate may be a rigid substrate that is not bent, and the polymer resin substrate may be a flexible substrate that may be bent or curved.

Each of the plurality of well areas WA includes a source area SA corresponding to a source electrode of the pixel transistor PTR, a drain area DA corresponding to a drain electrode thereof, and a channel area CH disposed between the source area SA and the drain area DA.

Each of the source area SA and the drain area DA may be an area doped with first-type impurities. A gate electrode GE of the pixel transistor PTR may overlap the well area WA in the third direction (Z-axis direction). The channel area CH may overlap the gate electrode GE in the third direction (Z-axis direction). The source area SA may be disposed on one side of the gate electrode GE, and the drain area DA may be disposed on the other side of the gate electrode GE.

A first semiconductor insulating film SINS1 may be disposed on the semiconductor substrate SSUB. The first semiconductor insulating film SINS1 may be formed as a silicon nitride (SiCN) or silicon oxide (SiOx)-based inorganic film, but the embodiment of the present specification is not limited thereto.

A semiconductor insulating film SINS2 may be disposed on the first semiconductor insulating film SINS1. The second semiconductor insulating film SINS2 may be formed as a silicon oxide (SiOx)-based inorganic film, but the embodiment of the present specification is not limited thereto.

A plurality of contact terminals CTE may be disposed on the second semiconductor insulating film SINS2. Each of the plurality of contact terminals CTE may be connected to any one of the gate electrode GE, the source area SA, and the drain area DA of each of the plurality of pixel transistors PTR through a hole penetrating through the first semiconductor insulating film SINS1 and the second semiconductor insulating film SINS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof.

A third semiconductor insulating film SINS3 may be disposed on a side surface of each of the plurality of contact terminals CTE. An upper surface of each of the plurality of contact terminals CTE may be exposed without being covered by the third semiconductor insulating film SINS3. The third semiconductor insulating film SINS3 may be formed as a silicon oxide (SiOx)-based inorganic film, but the embodiment of the present specification is not limited thereto.

The light emitting element backplane EBP includes first to eighth metal layers ML1 to ML8, reflective metal layers RL1 to RL4, a plurality of vias VA1 to VA10, and a step layer STPL. In addition, the light emitting element backplane EBP includes a plurality of interlayer-insulating films INS1 to INS10 disposed between the first to sixth metal layers ML1 to ML6.

The first to eighth metal layers ML1 to ML8 serve to implement a circuit of a sub-pixel SP by connecting the plurality of contact terminals CTE exposed from the semiconductor backplane SBP.

A first interlayer-insulating film INS1 may be disposed on the semiconductor backplane SBP. Each of the first vias VA1 may penetrate through the first interlayer-insulating film INS1 and be connected to the contact terminal CTE exposed from the semiconductor backplane SBP. Each of the first metal layers ML1 may be disposed on the first interlayer-insulating film INS1 and may be connected to the first via VA1.

A second interlayer-insulating film INS2 may be disposed on the first interlayer-insulating film INS1 and the first metal layers ML1. Each of the second vias VA2 may be connected to the first metal layer ML1 exposed by penetrating through the second interlayer-insulating film INS2. Each of the second metal layers ML2 may be disposed on the second interlayer-insulating film INS2 and may be connected to the second via VA2.

A third interlayer-insulating film INS3 may be disposed on the second interlayer-insulating film INS2 and the second metal layers ML2. Each of the third vias VA3 may be connected to the second metal layer ML2 exposed by penetrating through the third interlayer-insulating film INS3. Each of the third metal layers ML3 may be disposed on the third interlayer-insulating film INS3 and may be connected to the third via VA3.

A fourth interlayer-insulating film INS4 may be disposed on the third interlayer-insulating film INS3 and the third metal layers ML3. Each of the fourth vias VA4 may be connected to the third metal layer ML3 exposed by penetrating through the fourth interlayer-insulating film INS4. Each of the fourth metal layers ML4 may be disposed on the fourth interlayer-insulating film INS4 and may be connected to the fourth via VA4.

A fifth interlayer-insulating film INS5 may be disposed on the fourth interlayer-insulating film INS4 and the fourth metal layers ML4. Each of the fifth vias VA5 may be connected to the fourth metal layer ML4 exposed by penetrating through the fifth interlayer-insulating film INS5. Each of the fifth metal layers ML5 may be disposed on the fifth interlayer-insulating film INS5 and may be connected to the fifth via VA5.

A sixth interlayer-insulating film INS6 may be disposed on the fifth interlayer-insulating film INS5 and the fifth metal layers ML5. Each of the sixth vias VA6 may be connected to the fifth metal layer ML5 exposed by penetrating through the sixth interlayer-insulating film INS6. Each of the sixth metal layers ML6 may be disposed on the sixth interlayer-insulating film INS6 and may be connected to the sixth via VA6.

A seventh interlayer-insulating film INS7 may be disposed on the sixth interlayer-insulating film INS6 and the sixth metal layers ML6. Each of the seventh vias VA7 may be connected to the sixth metal layer ML6 exposed by penetrating through the seventh interlayer-insulating film INS7. Each of the seventh metal layers ML7 may be disposed on the seventh interlayer-insulating film INS7 and may be connected to the seventh via VA7.

An eighth interlayer-insulating film INS8 may be disposed on the seventh interlayer-insulating film INS7 and the seventh metal layers ML7. Each of the eighth vias VA8 may be connected to the seventh metal layer ML7 exposed by penetrating through the eighth interlayer-insulating film INS8. Each of the eighth metal layers ML8 may be disposed on the eighth interlayer-insulating film INS8 and may be connected to the eighth via VA8.

The first to eighth metal layers ML1 to ML8 and the first to eighth vias VA1 to VA8 may be formed of substantially the same material. The first to eighth metal layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. The first to eighth vias VA1 to VA8 may be formed of substantially the same material. The first to eighth interlayer-insulating films INS1 to INS8 may be formed as a silicon oxide (SiOx)-based inorganic film, but the embodiment of the present specification is not limited thereto.

A thickness of the first metal layer ML1, a thickness of the second metal layer ML2, a thickness of the third metal layer ML3, a thickness of the fourth metal layer ML4, a thickness of the fifth metal layer ML5, and a thickness of the sixth metal layer ML6 may be greater than a thickness of the first via VA1, a thickness of the second via VA2, a thickness of the third via VA3, a thickness of the fourth via VA4, a thickness of the fifth via VA5, and a thickness of the sixth via VA6, respectively. Each of the thickness of the second metal layer ML2, the thickness of the third metal layer ML3, the thickness of the fourth metal layer ML4, the thickness of the fifth metal layer ML5, and the thickness of the sixth metal layer ML6 may be greater than the thickness of the first metal layer ML1. The thickness of the second metal layer ML2, the thickness of the third metal layer ML3, the thickness of the fourth metal layer ML4, the thickness of the fifth metal layer ML5, and the thickness of the sixth metal layer ML6 may be substantially the same.

Each of a thickness of the seventh metal layer ML7 and a thickness of the eighth metal layer ML8 may be greater than each of the thickness of the first metal layer ML1, the thickness of the second metal layer ML2, the thickness of the third metal layer ML3, the thickness of the fourth metal layer ML4, the thickness of the fifth metal layer ML5, and the thickness of the sixth metal layer ML6. Each of the thickness of the seventh metal layer ML7 and the thickness of the eighth metal layer ML8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh metal layer ML7 and the thickness of the eighth metal layer ML8 may be substantially the same.

A ninth interlayer-insulating film INS9 may be disposed on the eighth interlayer-insulating film INS8 and the eighth metal layers ML8. The ninth interlayer-insulating film INS9 may be formed as a silicon oxide (SiOx)-based inorganic film, but the embodiment of the present specification is not limited thereto.

Each of the ninth vias VA9 may be connected to the eighth metal layer ML8 exposed by penetrating through the ninth interlayer-insulating film INS9. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof.

Each of first reflective electrodes RL1 may be disposed on the ninth interlayer-insulating film INS9 and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof.

Each of second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. For example, the second reflective electrodes RL2 may be formed of titanium nitride (TiN).

In a portion overlapping the first sub-pixel SP1, a step layer STPL may be disposed on the second reflective electrode RL2. The step layer STPL may not be disposed in a portion overlapping the second sub-pixel SP2 and the third sub-pixel SP3. The step layer STPL may be formed of a silicon carbon nitride (SiCN) or silicon oxide (SiOx)-based inorganic film, but the embodiments of the present specification are not limited thereto.

In portion overlapping the first sub-pixel SP1, a third reflective electrode RL3 may be disposed on the second reflective electrode RL2 and the step layer STPL. In portion overlapping the second and third sub-pixels SP2 and SP3, the third reflective electrode RL3 may be disposed on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. At least one of the first reflective electrode RL1, the second reflective electrode RL2, and the third reflective electrode RL3 may be omitted.

Each of fourth reflective electrodes RL4 may be disposed on the third reflective electrode RL3. The fourth reflective electrode RL4 may include a metal having a high reflectance to be advantageous in reflecting light. The fourth reflective electrode RL4 may be formed of aluminum (Al), a stacked structure (Ti/Al/Ti) of aluminum and titanium, a stacked structure (ITO/AI/ITO) of aluminum and ITO, an APC alloy, which is an alloy of silver (Ag), palladium (Pd), and copper (Cu), and a stacked structure (ITO/APC/ITO) of an APC alloy and ITO, but the embodiment of the present specification is not limited thereto.

A tenth interlayer-insulating film INS10 may be disposed on the ninth interlayer-insulating film INS9 and the fourth reflective electrode RL4. The tenth interlayer-insulating film INS10 may be formed as a silicon oxide (SiOx)-based inorganic film, but the embodiment of the present specification is not limited thereto.

Each of the tenth vias VA10 may be connected to the ninth metal layer ML9 exposed by penetrating through the tenth interlayer-insulating film INS10. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. Due to the step layer STPL, a thickness of the tenth via VA10 in the first sub-pixel SP1 may be smaller than a thickness of the tenth via VA10 in each of the second and third sub-pixels SP2 and SP3.

The light emitting element layer EML may be disposed on the light emitting element backplane EBP. The light emitting element layer EML may include light emitting elements LE each including a first electrode AND, a light emitting layer IL, and a second electrode CAT, and a pixel defining layer PDL.

The first electrode AND may be disposed on the tenth interlayer-insulating film INS10 and may be connected to the tenth via VA10. The first electrode AND may be connected to the drain area DA or the source area SA of the pixel transistor PTR through the tenth via VA10, the first to fourth reflective electrodes RL1 to RL4, the first to ninth vias VA1 to VA9, the first to eighth metal layers ML1 to ML8, and the contact terminal CTE. The first electrode AND may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. For example, the first electrode AND may be formed of titanium nitride (TiN).

The pixel defining layer PDL may be disposed on a partial area of the first electrode AND. The pixel defining layer PDL may cover an edge of the first electrode AND. The pixel defining layer PDL serves to partition the first light emitting areas EA1, the second light emitting areas EA2, and the third light emitting areas EA3.

The first light emitting area EA1 may be defined as an area in which the first electrode AND, the first light emitting layer IL1, and the second electrode CAT are sequentially stacked in the first sub-pixel SP1 to emit light. The second light emitting area EA2 may be defined as an area in which the first electrode AND, the second light emitting layer IL2, and the second electrode CAT are sequentially stacked in the second sub-pixel SP2 to emit light. The third light emitting area EA3 may be defined as an area in which the first electrode AND, the third light emitting layer IL3, and the second electrode CAT are sequentially stacked in the third sub-pixel SP3 to emit light.

The pixel defining layer PDL may include first to third pixel defining layers PDL1, PDL2, and PDL3. The first pixel defining layer PDL1 may be disposed on the edge of the first electrode AND, the second pixel defining layer PDL2 may be disposed on the first pixel defining layer PDL1, and the third pixel defining layer PDL3 may be disposed on the second pixel defining layer PDL2. The first pixel defining layer PDL1, the second pixel defining layer PDL2, and the third pixel defining layer PDL3 may be formed as a silicon oxide (SiOx)-based inorganic film, but the embodiment of the present specification is not limited thereto.

The light emitting layer IL may include a first light emitting layer IL1, a second light emitting layer IL2, and a third light emitting layer IL3. The first light emitting layer IL1, the second light emitting layer IL2, and the third light emitting layer IL3 may emit light of different colors. As an example, the first light emitting layer IL1 may emit red light, the second light emitting layer IL2 may emit green light, and the third light emitting layer IL3 may emit blue light, but the present disclosure is not limited thereto.

The first to third light emitting layers IL1, IL2, and IL3 disposed adjacent to each other in the first direction (X-axis direction) may be disconnected by the pixel defining layer PDL. The display panel 410 according to an embodiment may prevent leakage current between the sub-pixels SP1, SP2, and SP3 disposed adjacent to each other and prevent a color interference phenomenon by disconnecting the first to third light emitting layers IL1, IL2, and IL3 disposed adjacent to each other.

The second electrode CAT may be disposed on the light emitting layer IL. The second electrode CAT may be a common electrode. The second electrode CAT may be formed of a transparent conductive material (“TCO”) such as ITO or IZO capable of transmitting light, or a semi-transmissive conductive material such as magnesium (Mg), silver (Ag), or an alloy of magnesium (Mg) and silver (Ag). When the second electrode CAT is formed of a semi-transmissive conductive material, light emission efficiency may be increased in each of the first to third sub-pixels SP1, SP2, and SP3 by micro cavities.

The encapsulation layer TFE may be disposed on the light emitting element layer EML. The encapsulation layer TFE may include at least one inorganic film to prevent oxygen or moisture from permeating into the light emitting element layer EML. For example, the encapsulation layer TFE may include a first encapsulation layer TFEL and a second encapsulation layer TFE2.

The first encapsulation layer TFE1 may be disposed on the second electrode CAT, and the second encapsulation layer TFE2 may be disposed on the first encapsulation layer TFE1. The first encapsulation layer TFE1 and the second encapsulation layer TFE2 may be formed as a multi-film in which one or more inorganic films of a silicon nitride layer (SiNx), a silicon oxynitride layer (SiON), a silicon oxide layer (SiOx), a titanium oxide layer (TiOx), and an aluminum oxide layer (AlOx) are alternately stacked.

An adhesive layer APL may be a layer for increasing an interfacial adhesion between the encapsulation layer TFE and the cover layer CVL. The adhesive layer APL may be an organic film made of an acryl resin, an epoxy resin, a phenolic resin, a polyamide resin, a polyimide resin, or the like.

The cover layer CVL may be disposed on the adhesive layer APL. The cover layer CVL may be a glass substrate or a polymer resin such as resin. When the cover layer CVL is a glass substrate, the cover layer CVL may serve as an encapsulation substrate, and when the cover layer CVL is a polymer resin such as resin, the cover layer CVL may be applied directly on the adhesive layer APL.

A polarizing plate POL may be disposed on one surface of the cover layer CVL. The polarizing plate POL may be a structure for preventing deterioration in visibility due to reflection of external light. The polarizing plate POL may include a linear polarizing plate and a phase retardation film. As an example, the phase retardation film may be a λ/4 (quarter-wave) plate, but the embodiment of the present specification is not limited thereto.

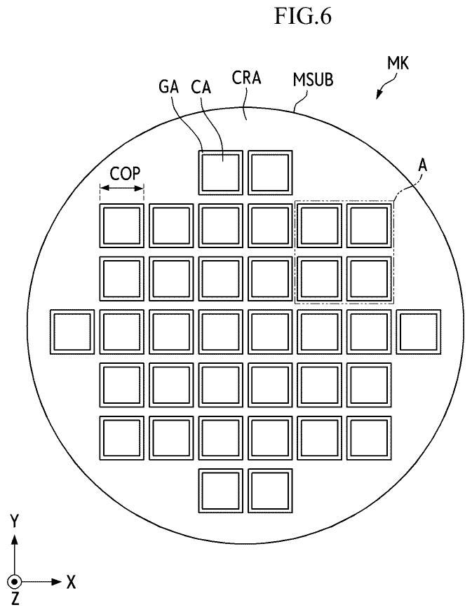

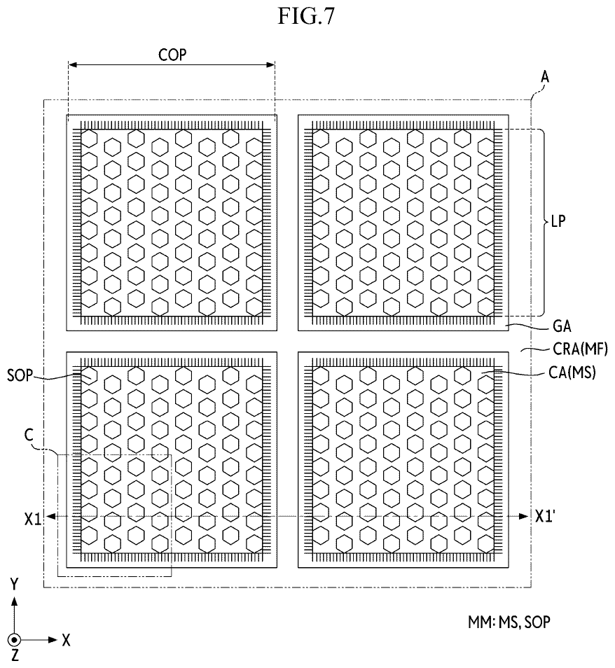

FIG. 6 is a schematic plan view of a mask according to an embodiment. FIG. 7 is an enlarged plan view of area A of FIG. 6. The mask according to an embodiment illustrated in FIG. 6 may be used in a process of depositing at least a portion of the light emitting layer IL of the display panel 410 described with reference to FIG. 5.

Referring to FIGS. 6 and 7, a mask MK according to an embodiment may be a mask used to manufacture an ultra-high resolution display. As an example, the mask MK may be a mask used to manufacture a display included in an extended reality (“XR”) device such as a VR device, AR device, or MR device.

The mask MK according to an embodiment may be used to perform a deposition process of the sub-pixels (SP1, SP2, and SP3 in FIG. 5) on a silicon wafer rather than a large-area substrate used in the conventional display. In the case of the display included in the extended reality device, since a screen thereof is positioned directly in front of the user's eyes, the display may have a small screen rather than a large-area screen. In addition, since the display is positioned close to the user's eyes, ultra-high resolution may be desirable. For example, the display included in the extended reality device may require resolution of approximately 1000 PPI or more, and preferably may require ultra-high resolution of 2000 PPI or more. Therefore, the mask MK according to an embodiment may be a mask used to manufacture such an ultra-high resolution display. The mask MK according to an embodiment may include all of the masks MK1, MK3, MK5, and MK7 described later.

The mask MK according to an embodiment may include a mask substrate MSUB.

The mask substrate MSUB according to an embodiment may include a silicon wafer. Since the silicon wafer may be processed more finely and precisely than the large-area substrate by utilizing technologies developed in the semiconductor process, the silicon wafer may be employed as a substrate of the ultra-high resolution display. The mask MK according to an embodiment may use the same silicon wafer to form pixels on the silicon wafer of such an ultra-high resolution display.

The mask substrate MSUB according to an embodiment may have a shape corresponding to the silicon wafer of the ultra-high resolution display. For example, the mask substrate MSUB may have the same size or shape as the silicon wafer of the ultra-high resolution display. However, the mask substrate MSUB is not limited thereto, and may also include a large-area substrate in another embodiment. For example, the mask substrate MSUB may also include materials such as glass, quartz, and polymer resin.

The mask MK according to an embodiment may include a plurality of cell areas CA, a grid area GA, and a cell peripheral area CRA.

According to an embodiment, a plurality of cell areas CA may be formed, and may be positioned to be spaced apart from each other. The cell area CA may be a portion positioned to overlap the mask opening COP.

In the plan view, the cell area CA may be an area where a mask membrane MM overlaps. The mask membrane MM may include a mask shadow MS and define a pixel opening SOP therein. In the plan view, the mask shadow MS may be integrally formed to surround the entirety of the pixel opening SOP. In other words, in the plan view, the mask shadow MS may be a pattern formed integrally while exposing the pixel opening SOP.

The grid area GA according to an embodiment may be positioned between the cell area CA and the cell peripheral area CRA. In the plan view, the grid area GA may be positioned to completely surround the cell area CA. In other words, in the plan view, the grid area GA may completely surround the mask opening COP.

In the plan view, the grid area GA may be an area where a ruler pattern LP overlaps. A plurality of ruler patterns LP may be disposed in an area overlapping the grid area GA. In the plan view, the plurality of ruler patterns LP may surround the mask opening COP and be spaced apart at regular intervals.

In the plan view, the plurality of ruler patterns LP may not overlap the mask membrane MM and the mask frame MF. In other words, in the plan view, the plurality of ruler patterns LP may not overlap the cell area CA and the cell peripheral area CRA. A major surface of the mask frame MF may be parallel to the X-axis direction and the Y-axis direction. As used herein, the “plan view” is a view in a direction (Z-axis direction) perpendicular to the major surface of the mask frame MF.

The cell peripheral area CRA according to an embodiment may be positioned to surround the grid area GA. The cell peripheral area CRA may be positioned to surround each cell area CA and grid area GA.

In the plan view, the cell peripheral area CRA may be an area where the mask frame MF overlaps. The mask frame MF may support the mask MK. In the plan view, the mask frame MF may surround the entireties of the ruler pattern LP and the mask membrane MM. In other words, in the plan view, the mask frame MF may surround the entirety of the mask opening COP.

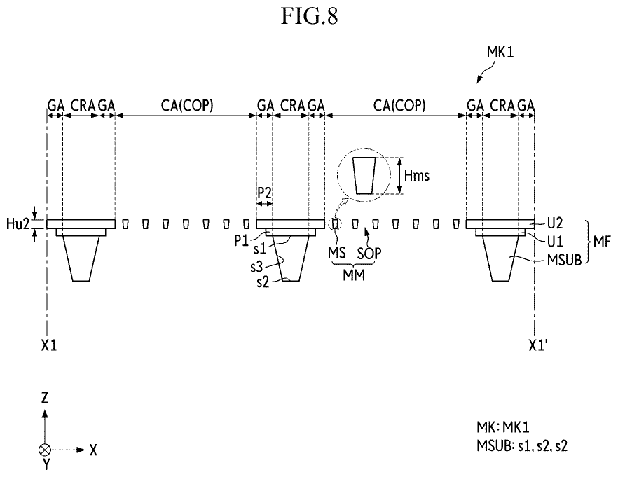

FIG. 8 is a cross-sectional view taken along line X1-X1′ of FIG. 7.

Referring to FIG. 8, the mask frame MF according to an embodiment may be positioned in a portion overlapping the cell peripheral area CRA and the grid area GA in a plan view. The mask frame MF may include a mask substrate MSUB, a first upper inorganic layer U1, and a second upper inorganic layer U2.

In some embodiments, the mask substrate MSUB may include an upper surface s1, a lower surface s2, and a side surface s3. The upper surface s1 may be one surface facing the first upper inorganic layer U1, the lower surface s2 may be one surface opposite to the upper surface s1, and the side surface s3 may be one surface connecting the upper surface s1 and the lower surface s2. The side surface s3 of the mask substrate MSUB may be an inclined surface. This may be caused by a portion of the mask substrate MSUB being removed through an etching process during the manufacturing process of the mask MK.

The first upper inorganic layer U1 according to an embodiment may be positioned on the mask substrate MSUB. The first upper inorganic layer U1 may be in contact with the upper surface s1 of the mask substrate MSUB and may cover the entirety of the upper surface s1.

The first upper inorganic layer U1 according to an embodiment may include a protrusion P1 that protrudes further toward the cell area CA than the side surface s3 of the mask substrate MSUB. The protrusion P1 of the first upper inorganic layer U1 may be a portion that protrudes further in the first direction (X-axis direction) than the side surface s3 of the mask substrate MSUB. Therefore, an undercut may be formed between the side surface s3 of the mask substrate MSUB and the protrusion P1 of the first upper inorganic layer U1.

The first upper inorganic layer U1 may include an inorganic insulating material. As an example, the first upper inorganic layer U1 may include any one of silicon oxide, silicon nitride, and silicon oxynitride.

The second upper inorganic layer U2 according to an embodiment may be positioned on the first upper inorganic layer U1. The second upper inorganic layer U2 may be in contact with the first upper inorganic layer U1 and may cover the entirety of the first upper inorganic layer U1.

The second upper inorganic layer U2 according to an embodiment may include a protrusion P2 that protrudes further toward the cell area CA than the side surface s3 of the mask substrate MSUB. The protrusion P2 of the second upper inorganic layer U2 may be a portion that protrudes further in the first direction (X-axis direction) than the side surface s3 of the mask substrate MSUB. Therefore, an undercut may be formed between the side surface s3 of the mask substrate MSUB and the protrusion P2 of the second upper inorganic layer U2.

The second upper inorganic layer U2 may include an inorganic insulating material. As an example, the second upper inorganic layer U2 may include any one of silicon oxide, silicon nitride, and silicon oxynitride. The second upper inorganic layer U2 may include the same material as the mask shadow MS, which will be described later. Details will be described later.

The first upper inorganic layer U1 and the second upper inorganic layer U2 according to an embodiment may have different stress properties. As an example, when the first upper inorganic layer U1 includes an inorganic insulating material having compressive stress, the second upper inorganic layer U2 may include an inorganic insulating material having tensile stress. The stress of the mask MK1 according to an embodiment may be adjusted by forming the first upper inorganic layer U1 and the second upper inorganic layer U2 to have stresses of different physical properties. In addition, the first upper inorganic layer U1 and the second upper inorganic layer U2 according to an embodiment may have etch ratios of different physical properties.

Depending on the embodiment, the first upper inorganic layer U1 may be omitted. When the first upper inorganic layer U1 is omitted, the second upper inorganic layer U2 may be positioned in contact with the upper surface s1 of the mask substrate MSUB.

The protrusion P1 of the first upper inorganic layer U1 and the protrusion P2 of the second upper inorganic layer U2 may be positioned in a portion overlapping the grid area GA. In other words, an area where the protrusion P1 of the first upper inorganic layer U1 and the protrusion P2 of the second upper inorganic layer U2 are positioned may be defined as the grid area GA. The protrusion P1 of the first upper inorganic layer U1 and the protrusion P2 of the second upper inorganic layer U2 may be formed because of having different etch ratios during the manufacturing process of the mask MK.

In a portion overlapping the grid area GA, the protrusion P2 of the second upper inorganic layer U2 may be positioned in contact with the protrusion P1 of the first upper inorganic layer U1. In a portion overlapping the grid area GA, the protrusion P2 of the second upper inorganic layer U2 may protrude further toward the cell area CA than the protrusion P1 of the first upper inorganic layer U1. Therefore, an undercut may be formed between the protrusion P1 of the first upper inorganic layer U1 and the protrusion P2 of the second upper inorganic layer U2.

The mask membrane MM according to an embodiment may be positioned in a portion overlapping the cell area CA. The mask membrane MM may include a plurality of mask shadows MS and define pixel openings SOP therein.

The pixel opening SOP may be positioned between the plurality of mask shadows MS adjacent to each other. The pixel opening SOP may be named “hole” or “mask hole.” The plurality of pixel openings SOP may penetrate through the mask frame MF along a thickness direction (e.g., third direction (Z-axis direction)) of the mask MK. The plurality of pixel openings SOP may be formed by etching portions of the mask substrate MSUB, the first upper inorganic layer U1, and the second upper inorganic layer U2 from a direction of the lower surface s2 of the mask substrate MSUB during the manufacturing process of the mask MK.

The mask shadow MS may be positioned to surround the pixel opening SOP. When a deposition material is evaporated from a deposition source inside a deposition device, the plurality of mask shadows MS may serve as a blocking portion that masks a substrate to be deposited (e.g., the display panel 410 or the backplane substrate). Accordingly, the deposition material generated from the deposition source may be deposited on a surface of the substrate to be deposited (e.g., the display panel 410 or the backplane substrate) through the pixel opening SOP.

The mask shadow MS according to an embodiment may be spaced apart from the second upper inorganic layer U2 with the pixel opening SOP interposed therebetween. The mask shadow MS may include the same material as the second upper inorganic layer U2. In the manufacturing process of the mask MK, the mask shadow MS and the second upper inorganic layer U2 may be integrally formed, and then formed into the illustrated shapes through a subsequent etching process.

In some embodiments, a height Hms of the mask shadow MS may be equal to a height Hu2 of the second upper inorganic layer U2 but is not limited thereto. As used herein, the “height” of an object may be a length of the object in the Z-axis direction.

In some embodiments, the mask shadow MS may have an inverted tapered shape but is not limited thereto.

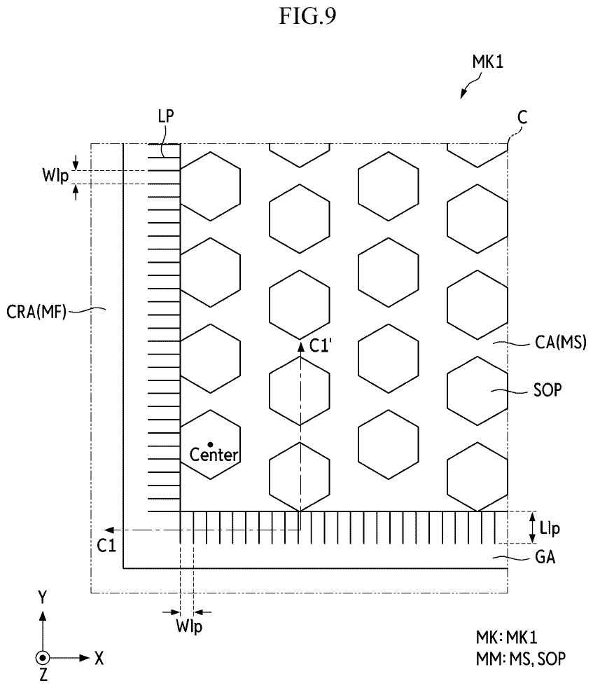

FIG. 9 is an enlarged plan view of area C of FIG. 7.

Referring to FIG. 9, in the plan view, a plurality of ruler patterns LP may be positioned in a portion overlapping the grid area GA.

In the plan view, the plurality of ruler patterns LP may surround the cell area CA at regular intervals. In other words, in the plan view, the plurality of ruler patterns LP may surround a pattern of the mask shadow MS at regular intervals. As an example, in the plan view, a gap Wlp between the plurality of ruler patterns LP adjacent to each other may range from 10 nanometers to 1000 nanometers.

The plurality of ruler patterns LP may measure a position precision of each pixel opening SOP based on a center of each pixel opening SOP, any portion of a vertex included in the pixel opening SOP, or any portion of a side included in the pixel opening SOP. In an embodiment, the ruler patterns LP may be located to point a certain location of each pixel opening SOP. For example, a virtual extension of every seventh ruler pattern LP in its longitudinal direction (e.g., X-axis direction) may reach the center of pixel opening SOP. Since the plurality of ruler patterns LP include nano-sized gaps, the plurality of ruler patterns LP may also be applied to the mask MK that produces an ultra-high resolution display panel. Since the mask MK1 according to an embodiment may measure the position precision of the pixel openings SOP on its own without a separate measuring device, the mask MK1 may facilitate measurement.

The plurality of ruler patterns LP may be spaced apart at equal intervals Wlp not only in the first direction (X-axis direction) but also in the second direction (Y-axis direction). It is illustrated in the drawing that the plurality of ruler patterns LP all include the same length Llp, but the present disclosure is not limited thereto. The ruler patterns LP may also include different lengths Llp from each other in another embodiment.

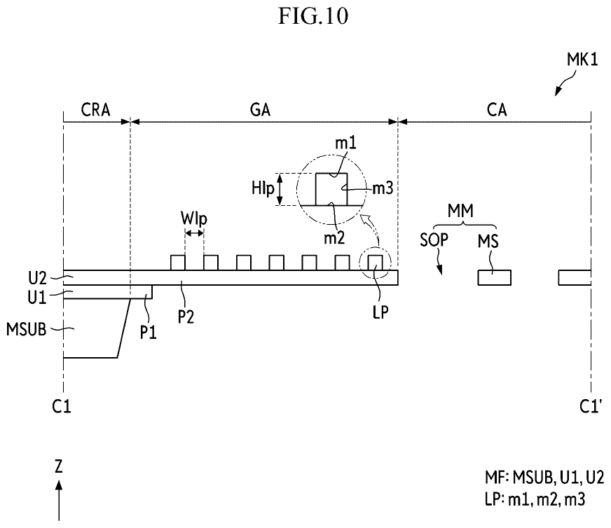

FIG. 10 is a cross-sectional view taken along line C1-C1′ of FIG. 9.

Referring to FIG. 10, the first upper inorganic layer U1 and the second upper inorganic layer U2 according to an embodiment may be stacked in the third direction (Z-axis direction) at a portion overlapping the cell peripheral area CRA. As described above, the first upper inorganic layer U1 may have the protrusion P1 in a portion overlapping the grid area GA, and the second upper inorganic layer U2 may have the protrusion P2 in a portion overlapping the grid area GA. In a portion overlapping the grid area GA, the protrusion P2 of the second upper inorganic layer U2 may protrude further in the direction toward the cell area CA than the protrusion P1 of the first upper inorganic layer U1. Therefore, an undercut may be formed between the protrusion P2 of the second upper inorganic layer U2 and the protrusion P1 of the first upper inorganic layer U1.

In a cross-sectional view, the plurality of ruler patterns LP may be positioned on the second upper inorganic layer U2 in a portion overlapping the grid area GA. The plurality of ruler patterns LP may be in contact with the second upper inorganic layer U2. The plurality of ruler patterns LP may not overlap the mask substrate MSUB in the third direction (Z-axis direction). As well, the plurality of ruler patterns LP may not overlap the mask membrane MM in the third direction (Z-axis direction). In other words, the plurality of ruler patterns LP may not overlap the cell area CA and the cell peripheral area CRA.

In a cross-sectional view, the plurality of ruler patterns LP may be spaced apart from the mask shadow MS with the pixel opening SOP interposed therebetween.

The plurality of ruler patterns LP may overlap the protrusion P2 of the second upper inorganic layer U2 in the third direction (Z-axis direction). It is illustrated in the drawing that the plurality of ruler patterns LP does not overlap the protrusion P1 of the first upper inorganic layer U1, but the present disclosure is not limited thereto. Depending on the embodiment, the plurality of ruler patterns LP may also be positioned to overlap the protrusion P1 of the first upper inorganic layer U1 in the third direction (Z-axis direction).

In a cross-sectional view, the plurality of ruler patterns LP may be spaced apart at regular intervals Wlp. As an example, in a cross-sectional view, a gap Wlp between the plurality of ruler patterns LP adjacent to each other may range from 10 nanometers to 1000 nanometers.

In some embodiments, the ruler pattern LP may include either an inorganic insulating material or a metallic material.

For example, when the ruler pattern LP includes an inorganic insulating material, the ruler pattern LP may include any one of silicon oxide, silicon nitride, and silicon oxynitride.

In some embodiments, when the ruler pattern LP includes an inorganic insulating material, the height Hlp of the ruler pattern LP may range from 0.2 micrometers to 3 micrometers.

For example, when the ruler pattern LP includes a metallic material, the ruler pattern LP may include copper (Cu), aluminum (Al), tungsten (W), molybdenum (Mo), chromium (Cr), gold (Au), titanium (Ti), nickel (Ni), and neodymium (Nd).

In some embodiments, when the ruler pattern LP includes a metallic material, the height Hlp of the ruler pattern LP may range from 50 nanometers to 500 nanometers.

It is illustrated in the drawing that the heights Hlp of the plurality of ruler patterns LP are the same, but the present disclosure is not limited thereto. Depending on the embodiment, the height Hlp of each ruler pattern LP may be differently formed.

In a cross-sectional view, the ruler pattern LP may include an upper surface m1, a lower surface m2, and a side surface m3. The lower surface m2 of the ruler pattern LP may be one surface in contact with the second upper inorganic layer U2, the upper surface m1 thereof may be one surface opposite to the lower surface m2, and the side surface m3 thereof may be a surface connecting the upper surface m1 and the lower surface m2.

In some embodiments, in a cross-sectional view, the ruler pattern LP of the mask MK1 may have a cylindrical shape. That is, the upper surface m1 and the lower surface m2 of the ruler pattern LP may have the same width. However, the ruler pattern LP is not limited thereto and may have various shapes depending on the embodiment. Details will be described later.

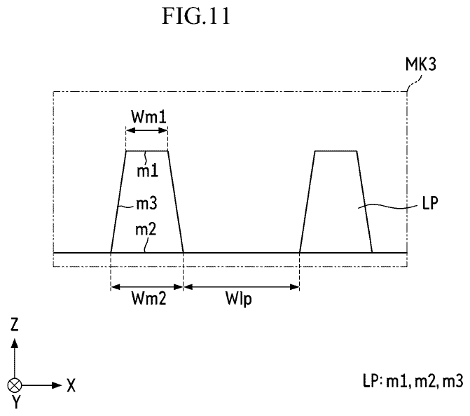

FIGS. 11 to 13 are cross-sectional views illustrating various shapes of a ruler pattern of FIG. 10, according to still another embodiment.

Referring to FIGS. 11 to 13, masks MK3, MK5, and MK7 described later may have a ruler pattern LP of a different shape from the mask MK1 described above. Hereinafter, the commonalities between the mask MK1 and the masks MK3, MK5, and MK7 will be omitted and the differences therebetween will be described later.

As illustrated in FIG. 11, a ruler pattern LP included in the mask MK3 is different from the ruler pattern LP included in the mask MK1 in that a width Wm1 of an upper surface m1 of the ruler pattern LP may be smaller than a width Wm2 of a lower surface m2. In addition, a side surface m3 of the ruler pattern LP included in the mask MK3 may be an inclined surface. That is, in a cross-sectional view, the ruler pattern LP included in the mask MK3 may have a trapezoidal shape. This may be caused by a portion of the ruler pattern LP being removed through an etching process during a manufacturing process of the mask MK3.

The plurality of ruler patterns LP included in the mask MK3 may be spaced apart at regular intervals Wlp. As an example, a gap Wlp between the plurality of ruler patterns LP may range from 10 nanometers to 1000 nanometers. The redundant descriptions will be omitted.

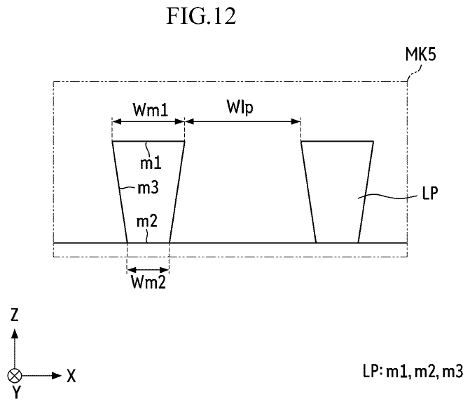

As illustrated in FIG. 12, a ruler pattern LP included in the mask MK5 is different from the ruler pattern LP included in the mask MK1 in that a width Wm1 of an upper surface m1 of the ruler pattern LP may be greater than a width Wm2 of a lower surface m2. In addition, a side surface m3 of the ruler pattern LP included in the mask MK5 may be an inclined surface. That is, in a cross-sectional view, the ruler pattern LP included in the mask MK5 may have an inverted tapered shape. This may be caused by a portion of the ruler pattern LP being removed through an etching process during a manufacturing process of the mask MK5.

The plurality of ruler patterns LP included in the mask MK5 may be spaced apart at regular intervals Wlp. As an example, a gap Wlp between the plurality of ruler patterns LP may range from 10 nanometers to 1000 nanometers. The redundant descriptions will be omitted.

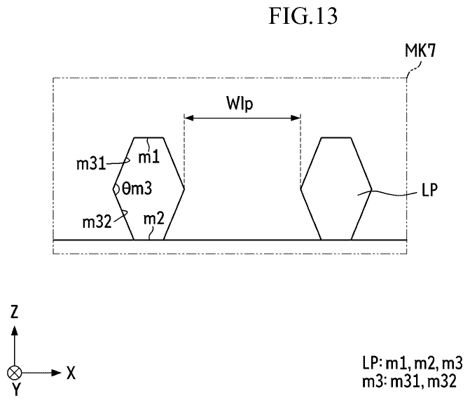

As illustrated in FIG. 13, a ruler pattern LP included in the mask MK7 is different from the ruler pattern LP included in the mask MK1 in that a side surface m3 includes a first side surface m31 and a second side surface m32. The first side surface m31 of the ruler pattern LP may be one surface connected to the upper surface m1, and the second side surface m32 of the ruler pattern LP may be one surface connected to the lower surface m2. The upper surface m1 and the lower surface m2 may be connected by the first side surface m31 and the second side surface m32.

The first side surface m31 and the second side surface m32 of the ruler pattern LP included in the mask MK7 may be inclined surfaces, and an inclination angle θm3 formed by the first side surface m31 and the second side surface m32 may be an obtuse angle. This may be caused by a portion of the ruler pattern LP being removed through an etching process during a manufacturing process of the mask MK5. Other redundant descriptions will be omitted.

The plurality of ruler patterns LP included in the mask MK7 may be spaced apart at regular intervals Wlp. As an example, a gap Wlp between the plurality of ruler patterns LP may range from 10 nanometers to 1000 nanometers. The redundant descriptions will be omitted.

The masks MK3, MK5, and MK7 may include a plurality of ruler patterns LP in portions overlapping the grid area GA. The plurality of ruler patterns LP included in the masks MK3, MK5, and MK7 may be spaced apart at nanoscale intervals. Therefore, the masks MK3, MK5, and MK7 may measure the position precision of the pixel openings SOP on its own without a separate measuring device, thereby facilitating measurement.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A deposition mask including a cell area, a cell peripheral area surrounding the cell area, and a grid area positioned between the cell area and the cell peripheral area in a plan view, the deposition mask comprising:
a mask membrane disposed in the cell area, including a mask shadow, and defining a pixel opening therein;
a mask frame disposed in the cell peripheral area and the grid area; and
a plurality of ruler patterns disposed in the grid area,
wherein the plurality of ruler patterns are adjacent to each other in a direction parallel to a major surface of the mask frame and spaced apart at equal intervals.

2. The deposition mask of claim 1, wherein the mask frame includes a mask substrate disposed in the cell peripheral area and an upper inorganic layer positioned on the mask substrate, and
the upper inorganic layer includes a protrusion that protrudes further toward the cell area than a side surface of the mask substrate positioned toward the cell area.

3. The deposition mask of claim 2, wherein the protrusion of the upper inorganic layer is disposed in the grid area.

4. The deposition mask of claim 2, wherein the plurality of ruler patterns is positioned on the upper inorganic layer, and
the plurality of ruler patterns overlaps the protrusion of the upper inorganic layer in a direction perpendicular to the major surface of the mask frame.

5. The deposition mask of claim 4, wherein the plurality of ruler patterns includes an inorganic insulating material.

6. The deposition mask of claim 5, wherein a height of each of the ruler patterns in the direction perpendicular to the major surface of the mask frame is equal to or more than 0.2 micrometer and equal to or less than 3.0 micrometer.

7. The deposition mask of claim 4, wherein the plurality of ruler patterns includes metal.

8. The deposition mask of claim 7, wherein a height of each of the ruler patterns in the direction perpendicular to the major surface of the mask frame is equal to or more than 50 nanometers and equal to or less than 500 nanometers.

9. The deposition mask of claim 1, wherein a gap between the plurality of ruler patterns adjacent to each other in the direction parallel to the major surface of the mask frame is equal to or more than 10 nanometers and equal to or less than 1000 nanometers.

10. The deposition mask of claim 1, wherein in a cross-sectional view, each of the ruler patterns has a cylindrical shape.

11. The deposition mask of claim 1, wherein in a cross-sectional view, each of the ruler patterns has a trapezoidal shape.

12. The deposition mask of claim 1, wherein in a cross-sectional view, each of the ruler patterns has an inverted tapered shape.

13. The deposition mask of claim 2, wherein each of the ruler patterns includes a lower surface facing the upper inorganic layer, an upper surface opposite to the lower surface, and a side surface connecting the upper surface and the lower surface, and
the side surface of each of the ruler patterns includes a first side surface connected to the upper surface and a second side surface connected to the lower surface.

14. The deposition mask of claim 13, wherein an inclination angle formed by the first side surface and the second side surface is an obtuse angle.

15. The deposition mask of claim 1, wherein at least one of the ruler patterns is located to point a predetermined position of the pixel opening.

16. A deposition mask including a cell area, a cell peripheral area surrounding the cell area, and a grid area positioned between the cell area and the cell peripheral area in a plan view, the deposition mask comprising:
a mask membrane disposed in the cell area, defining a pixel opening therein, and including a mask shadow surrounding the pixel opening;
a mask frame disposed in the cell peripheral area and the grid area and defining a mask opening therein; and
a plurality of ruler patterns disposed in the grid area,
wherein in the plan view, the plurality of ruler patterns are positioned adjacent to each other and spaced at equal intervals.

17. The deposition mask of claim 16, wherein in the plan view, a gap between the plurality of ruler patterns adjacent to each other is equal to or more than 10 nanometers and equal to or less than 1000 nanometers.

18. The deposition mask of claim 17, wherein in the plan view, the mask opening overlaps the cell area, and
in the plan view, the plurality of ruler patterns are positioned to surround the mask opening.

19. The deposition mask of claim 18, wherein in the plan view, the ruler patterns surround an entirety of the mask membrane, and
in the plan view, the mask frame surrounds an entirety of the ruler patterns.

20. The deposition mask of claim 19, wherein in the plan view, the mask frame includes a mask substrate including silicon, and
in the plan view, the mask substrate has a circular shape.
